(19) United States
(12) Patent Application Publication
(10) Pub. No.: US 2012/0014076 A1
(43) Pub. Date: Jan. 19, 2012

(54) CARD-TYPE ELECTRONIC CIRCUIT MODULE

(75) Inventors: Toshiyuku ABE, Miyagi-ken (JP); Kazuhiro SASAKI, Miyagi-ken (JP)

(73) Assignee: ALPS ELECTRIC CO., LTD., Tokyo (JP)

(21) Appl. No.: 13/179,412

(22) Filed: Jul. 8, 2011

(30) Foreign Application Priority Data
Jul. 15, 2010 (JP) 2010-160851

(51) Int. Cl. H05K 5/00

(52) U.S. Cl. 361/752

(57) ABSTRACT

An SD card (1) includes a card-shaped housing (4) which is formed by assembling insulating upper and lower covers (2 and 3), and a circuit board (5) which is accommodated in the housing (4). The circuit board (5) extends along an inner wall (2a) of the upper cover (2). Terminal electrodes (6) are fixed near one side end of the lower cover (3) by insert molding and are exposed to the outside, and reinforcing ribs (3d) configured to make contact with the circuit board (5) are formed thereon. Wiring patterns are formed on the circuit board (5), and electronic components (8 and 8a) are mounted on a principal surface (5a). Elastic pieces (9) which extend from the terminal electrodes (6) to the inside of the housing (4) are in elastic-contact with connecting land portions (7) of the wiring patterns disposed at one end of the principal surface (5a).

### CLAIM OF PRIORITY

This application claims benefit of Japanese Patent Application No. 2010-160851 filed on Jul. 15, 2010, which is hereby incorporated by reference.

### BACKGROUND OF THE INVENTION

1. Field of the Invention

The invention relates to a card-type electronic circuit module such as an SD card configured to be fitted into a card slot of an external electronic device such as a PC. Particularly, the invention relates to a card-type electronic circuit module in which tall electronic components are incorporated.

2. Description of the Related Art

In general, memory cards such as an SD card have electronic components mounted on a circuit board which is accommodated in a card-shaped housing, and a plurality of terminal electrodes arranged on the circuit board is exposed to the outside near one side edge of the housing. A memory card of this type is configured to be removably attached to an external electronic device such as a personal computer (PC) or a digital camera. When the memory card is inserted and fitted into a card slot of the external electronic device with the terminal electrode side facing forward, these terminal electrodes come into press-contact with the corresponding connection electrodes of the external electronic device. Thus, both terminals are electrically connected, and signals can be communicated between the memory card and the external electronic device. Thus, the outside dimensions of the memory card of this type, the arrangement and height position of the terminal electrodes, and the like are determined by the standards. For example, in the case of the SD card, the overall thickness is 2.1 mm, and nine terminal electrodes are arranged in a predetermined arrangement at a predetermined height from the bottom surface thereof and exposed to the outside.

In the related art, a card-type electronic circuit module like an IC card, in which a radio communication function is incorporated so that radio signals can be transmitted and received has been used in practice. However, when a radio communication function is incorporated into a small and thin module like an SD card, there is a problem in that it is difficult to dispose tall electronic components which are ideally used in a radio communication circuit or the like in the housing. That is, as shown in FIG. 12, in general, an SD card has terminal electrodes 22 which are arranged at one end of the principal surface of a circuit board 21 and which are exposed at a predetermined height position from the bottom surface of a housing 20, whereby the height of the circuit board 21 in the housing 20 is defined. Thus, the circuit board 21 divides the inner space S3 of the housing 20 into an upper space 51 and a lower space S2. In this case, electronic components which can be mounted on the circuit board 21 and disposed inside the housing 20 are limited to those having a lower height than the height dimension of the upper space S1 or the lower space S2. Thus, it may be difficult to use tall electronic components which are ideally used in a radio communication circuit or the like.

In the related art, in order to solve this problem, a card-type electronic circuit module in which a terminal board having terminal electrodes arranged thereon is stacked on a part of a circuit board in order to enable tall electronic components to be disposed in the housing is proposed (for example, see Japanese Patent No. 3894031). According to the related art, as shown in FIG. 13, the circuit board 21 is accommodated so as to extend along one of the mutually facing inner walls of the housing 20, and the terminal board 23 is placed and fixed to one end of the principal surface of the circuit board 21. Moreover, the terminal electrodes 22 arranged on the lower surface of the terminal board 23 are exposed to the outside near one side edge of the housing 20, and connection electrodes 24 arranged on the upper surface of the terminal board 23 are electrically connected to the corresponding terminal electrodes 22 through through-holes or the like. Moreover, these connection electrodes 24 are soldered to wiring patterns (not shown) of the circuit board 21. In the case of the card-type electronic circuit module having such a configuration, since the inner space S3 of the housing 20 is vertically divided, a tall electronic component (for example, a chip antenna) 25 ideally used in a radio communication circuit or the like can be mounted on the circuit board 21 and disposed in the housing 20. Moreover, by appropriately selecting the thickness of the terminal board 23, the terminal electrodes 22 can be exposed to a predetermined height position from the bottom surface of the housing 20.

### SUMMARY OF THE INVENTION

However, in the card-type electronic circuit module of the related art disclosed in Japanese Patent No. 3894031, since the terminal board 23 is placed and fixed to one end of the principal surface of the circuit board 21, there is a problem in that the area for a region on the principal surface which can be used as a component mounting surface decreases. Particularly, in the case of small modules like an SD card, it is not easy to add a radio communication function in a small mounting region. Moreover, since it is also difficult to secure a mechanical structure while placing and fixing the circuit board 21 so as to be electrically connected to the terminal board 23, it is difficult to realize cost-reduction and obtain sufficient durability. That is, in the case of the card-type electronic circuit module of the related art, strong shearing force acts on the soldering portions of the terminal board 23 due to the clamping force applied to the housing when attaching or removing it to/from the card slot of the external electronic device. Thus, there is a problem in that the electrical connection between the terminal electrodes 22 and the circuit board 21 is impaired by repeated attachment and removal.

The invention has been made in view of the problems of the related art. An advantage of some aspects of the invention is to provide a card-type electronic circuit module which is configured to be capable of mounting tall electronic components on a circuit board accommodated in a housing while designing the outside dimensions and the height position of the terminal electrodes according to the standards, and securing a wide mounting region on the principal surface of the circuit board, thus making conduction faults of the terminal electrodes less likely to occur.

According to an aspect of the invention, there is provided a card-type electronic circuit module including: a circuit board on which wiring patterns are formed and electronic components are mounted; an insulating housing in which the circuit board is accommodated; terminal electrodes which are fixed near one side end of the housing and exposed to the outside; and conductive internal connection means for realizing conduction between the terminal electrodes and the wiring patterns within the housing, wherein the circuit board is extended along one of mutually facing inner walls of the housing, and the internal connection means are in elastic-contact with connecting land portions of the wiring patterns disposed at one end of the principal surface of the circuit board.

In the card-type electronic circuit module having such a configuration, the terminal electrodes which are fixed near one side end of the housing are electrically connected to the wiring patterns (connecting land portions) of the circuit board through the conductive internal connection means. Moreover, it is not necessary to form terminal electrodes on the principal surface of the circuit board. Thus, even when the outside dimensions of the housing and the height position of the terminal electrodes are set according to the standards, it is possible to extend the circuit board along one of the mutually facing inner walls of the housing to thereby secure a high inner space between the principal surface of the circuit board and the inner wall. Therefore, it is possible to mount tall electronic components which are ideally used in a radio communication circuit or the like on the principal surface of the circuit board and dispose the electronic components within the housing. Moreover, the internal connection means are in elastic-contact with the wiring patterns at one end of the principal surface of the circuit board, and it is not necessary to form terminal electrodes on the principal surface. Thus, it is possible to secure a wide mounting region on the principal surface of the circuit board. Furthermore, the clamping force applied to the housing when attaching and removing the module to/from a card slot of an external electronic device acts as an external force that elastically deforms the internal connection means. Thus, the clamping force is not likely to generate stress that impairs conduction between the internal connection means and the wiring patterns. Therefore, conduction faults of the terminal electrodes are not likely to occur even when attaching and removal is repeated.

In the above configuration, although the means for fixing the terminal electrodes to the housing is not particularly limited, it is preferable to fix the terminal electrodes by insert molding. By doing so, an assembling property can be improved.

In the above configuration, it is preferable that the internal connection means be realized by elastic pieces which extend from the terminal electrodes to the inside of the housing, and that distal ends of the elastic pieces be in elastic-contact with the connecting land portions. By doing so, it is possible to reduce the number of components and improve conduction reliability.

In the above configuration, it is preferable that reinforcing ribs which protrude from the vicinity of the terminal electrodes and make contact with the principal surface of the circuit board be formed on the housing. By doing so, the clamping force applied to the housing when attaching and removing the module to/from the card slot of the external electronic device can be received by the reinforcing ribs. Thus, it is possible to suppress positional shifts of the terminal electrodes and the internal connection means due to the clamping force as much as possible and to extend the lifespan of the card-type electronic circuit module.

### BRIEF DESCRIPTION OF THE DRAWINGS

FIG. 1 is a perspective view of an SD card according to an embodiment of the invention.

FIG. 2 is a bottom view of the SD card.

FIG. 3 is a cross-sectional view taken along the line A-A in FIG. 2.

FIG. 4 is an enlarged view of a part C in FIG. 3.

FIG. 5 is a cross-sectional view taken along the line B-B in FIG. 2.

FIG. 6 is an enlarged view of a part D in FIG. 5.

FIG. 7 is a top view of the SD card.

FIG. 8 is a side view of the SD card.

FIG. 9 is an exploded perspective view of the SD card as seen obliquely from above.

FIG. 10 is an enlarged view of a part E in FIG. 9.

FIG. 11 is an exploded perspective view of the SD card as seen obliquely from below.

FIG. 12 is a schematic cross-sectional view of a general SD card.

FIG. 13 is a schematic cross-sectional view of an SD card according to the related art.

### DESCRIPTION OF THE PREFERRED EMBODIMENTS

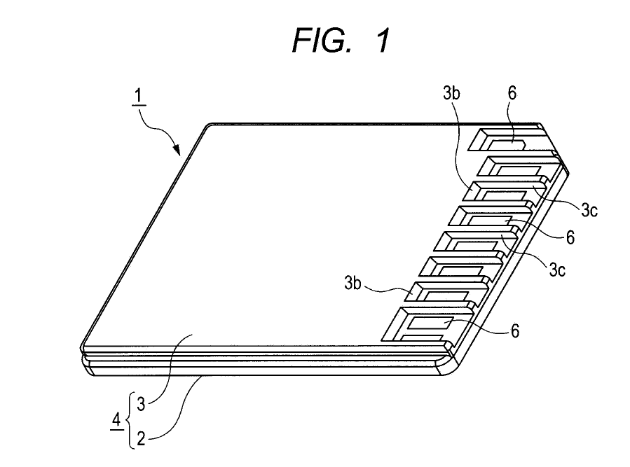

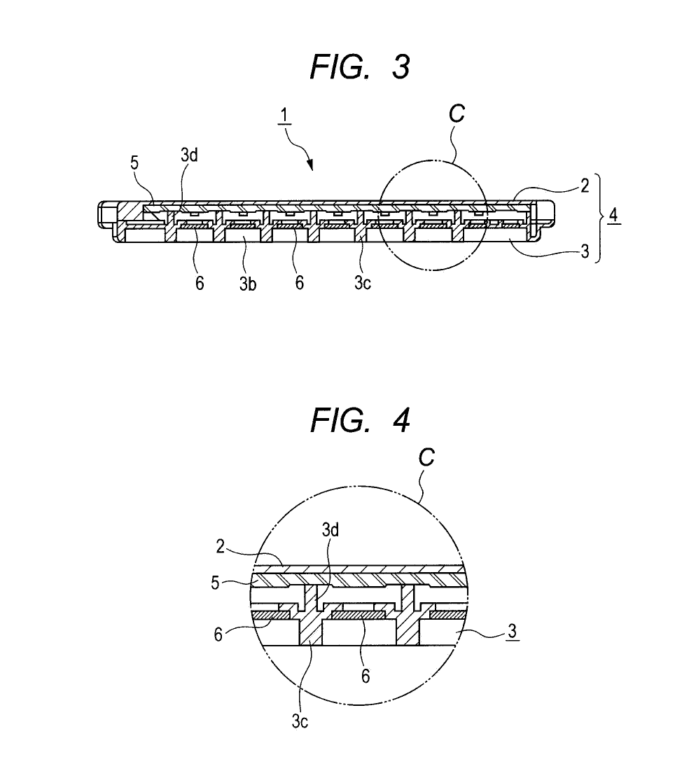

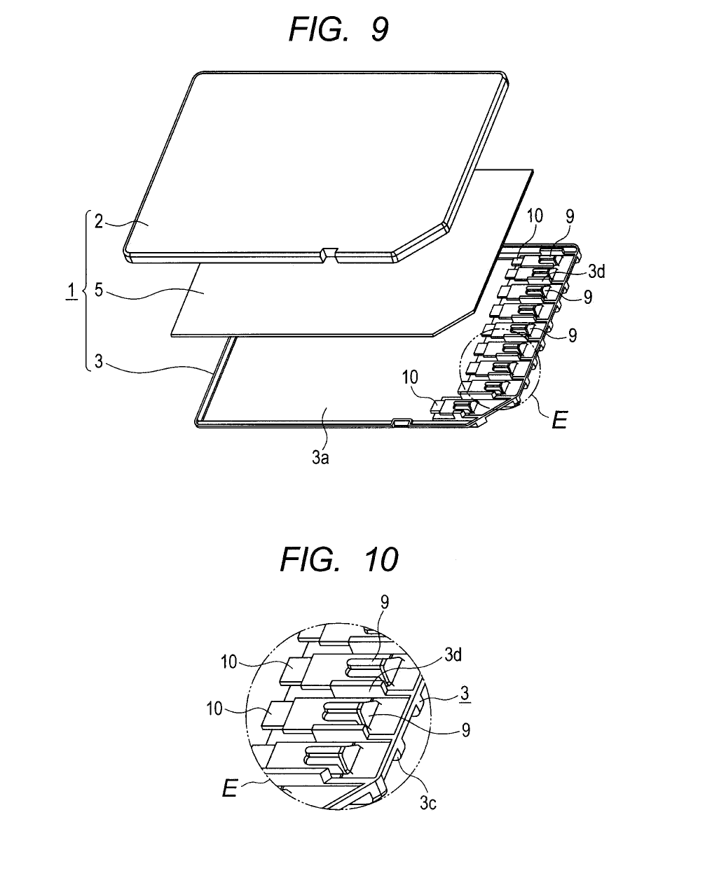

Hereinafter, a card-type electronic circuit module according to an embodiment of the invention will be described with reference to FIGS. 1 to 11. This card-type electronic circuit module is designed as an SD card which is a memory card, and has a radio communication function is added thereto by incorporating a radio communication circuit, an antenna, or the like.

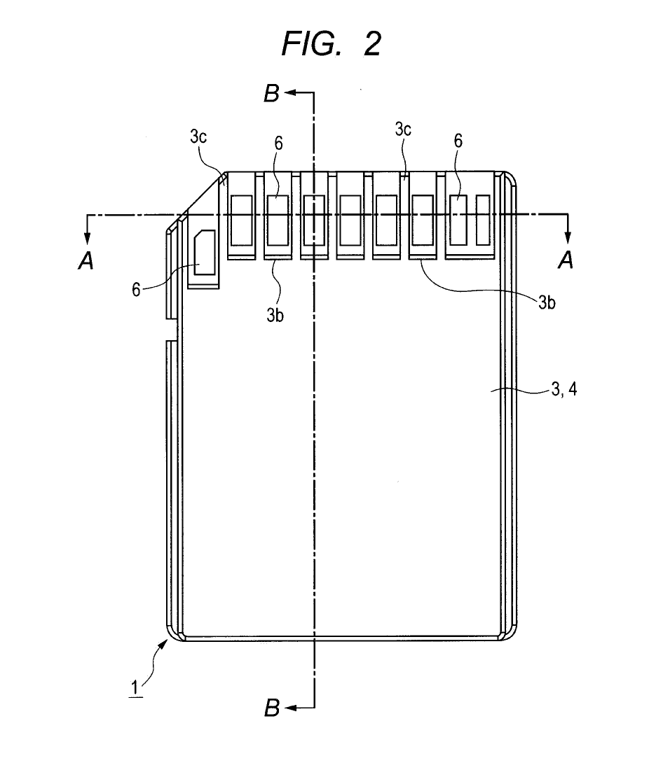

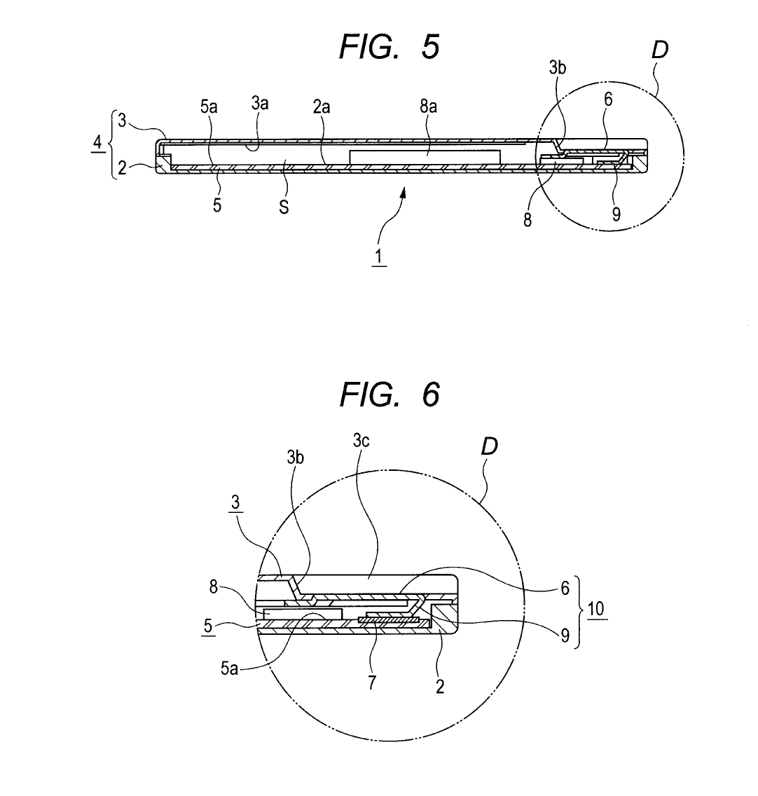

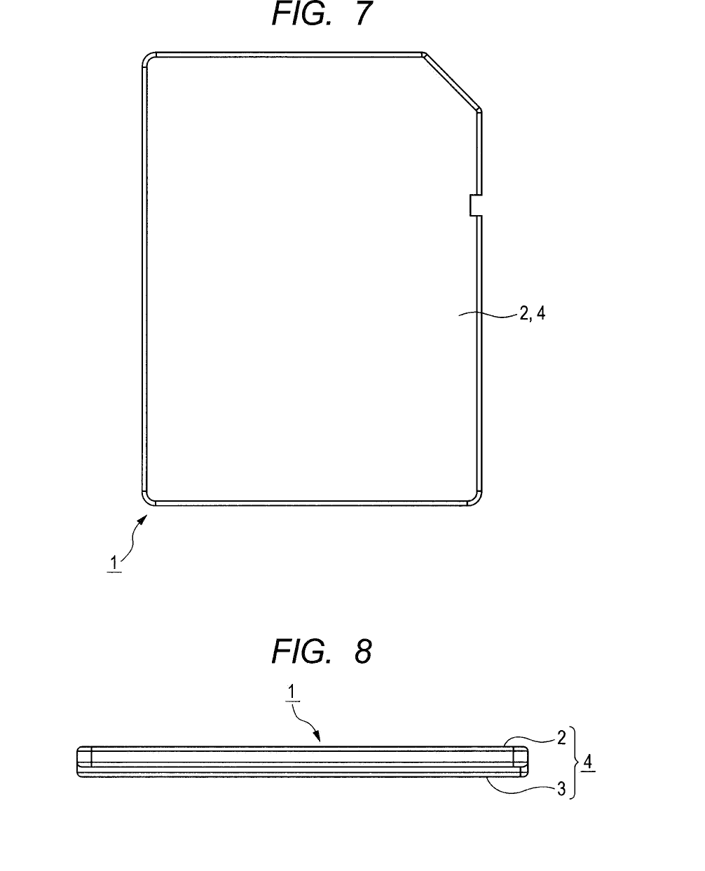

An SD card 1 according to the present embodiment has an appearance as shown in FIGS. 1 and 2 when seen from a bottom side thereof. Moreover, the SD card 1 has an appearance as shown in FIGS. 7 and 8 when seen from top and later sides thereof, respectively. As will be clear from FIGS. 5, 9, and 11, the SD card 1 is configured to mainly include a card-shaped housing 4 which is formed by assembling an upper cover 2 and a lower cover 3 formed of a synthetic resin, and a circuit board 5 accommodated in the housing 4. Moreover, nine terminal electrodes 6 are fixed near one side edge of the lower cover 3 and exposed to the outside. Furthermore, wiring patterns (lead-out patterns and the like are not shown) including connecting land portions 7 are formed on the circuit board 5, and various electronic components 8 and 8a are mounted on a principal surface 5a of the circuit board 5.

The upper and lower covers 2 and 3 constituting the housing 4 are approximately rectangular molded products formed of an insulating synthetic resin, and one side of each cover is notched in order to prevent an insertion error. Moreover, nine terminal electrodes 6 are formed in a predetermined arrangement near one side edge of the lower cover 3 by insert molding. The upper and lower covers 2 and 3 are assembled in a box-like shape in a state where their inner walls 2a and 3a facing each other with the circuit board 5 disposed therebetween. The peripheral portions of both covers 2 and 3 are integrated by snap connection or the like, whereby the housing 4 is formed. When the SD card 1 is inserted and fitted into a card slot of an external electronic device (not shown) with the terminal electrodes 6 side facing forward, these terminal electrodes 6 come into press-contact with the corresponding connection electrodes of the external electronic device. Thus, both terminals are electrically connected, and signals can be communicated between the SD card 1 and the external electronic device.

As will be understood from FIGS. 1, 4, and 6, steps 3b and partition walls 3c are formed near the respective terminal electrodes 6 on the bottom surface side of the lower cover 3. The steps 3b are formed so that the terminal electrodes 6 are disposed at a predetermined height position from the bottom surface of the lower cover 3. The partition walls 3c are formed as partitions between neighboring terminal electrodes 6. Due to presence of these partition walls 3c, the connection electrodes of the external electronic device can make contact with only the corresponding terminal electrodes 6. Moreover, as shown in FIGS. 4 and 10, reinforcing ribs 3d which are projections shorter than the partition walls 3c are formed at positions on the top surface side of the lower cover 3 where they overlap with partition walls 3c. These reinforcing ribs 3d come in contact with the principal surface 5a of the circuit board 5 near the connecting land portions 7.

As shown in FIGS. 6 and 10, elastic pieces 9 having such a shape that they are bent back into the housing 4 are extended from the terminal electrodes 6. That is, conductive metal pieces 10 which are processed to be bent in an approximate J-shape in a cross-sectional view thereof are inserted into a mold to form the lower cover 3. In this way, a set of parts of the conductive metal pieces 10 are used as the flat plate-like terminal electrodes 6 which are exposed to the outside, and portions which are extended from the terminal electrodes 6 in a bent-back shape are used as the elastic pieces 9. The distal ends of the elastic pieces 9 of the respective conductive metal pieces 10 are in elastic-contact with the corresponding connecting land portions 7 of the circuit board 5. Although not shown in the drawings, the distal ends of the elastic pieces 9 are electrically and mechanically connected to the connecting land portions 7 by soldering or a conductive adhesive agent.

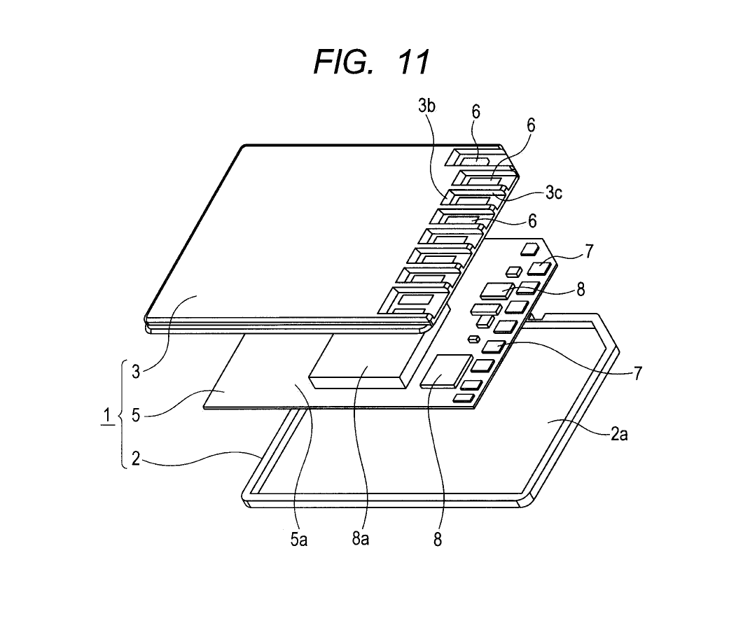

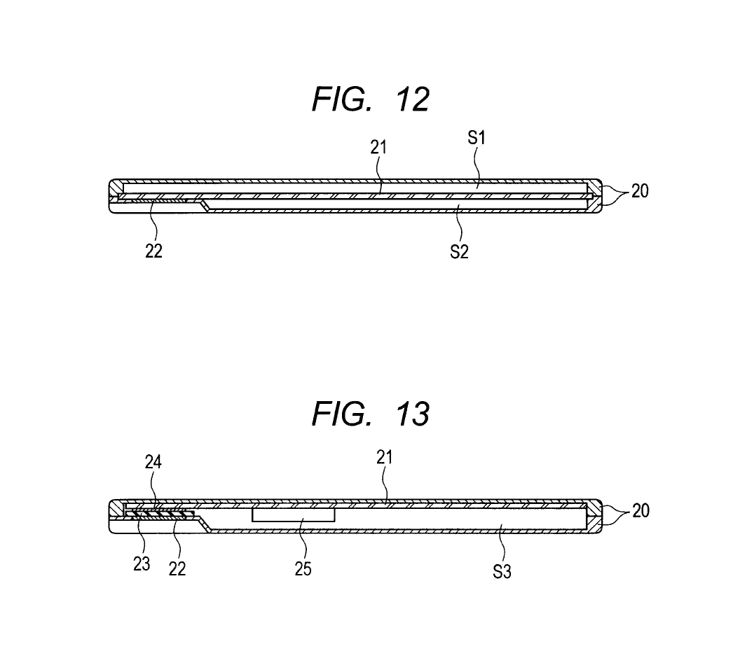

The circuit board 5 is incorporated into the upper cover 2 in an aligned state so as to extend along the inner wall 2a, and the upper and lower covers 2 and 3 are integrated with each other, whereby the circuit board 5 is fixed within the housing 4. As above, since the circuit board 5 extends along the inner wall 2a of the upper cover 2 within the housing 4, a high inner space S is formed between the principal surface 5a of the circuit board 5 and the inner wall 3a of the lower cover 3 as shown in FIG. 5. A tall electronic component 8a which is ideally used in a radio communication circuit, such as a chip antenna or an inductor, is mounted on the principal surface 5a of the circuit board 5, and the electronic component 8a can be disposed in the high inner space S without difficulty. As shown in FIG. 11, nine connecting land portions 7 are formed in a predetermined arrangement near one side edge of the principal surface 5a of the circuit board 5, and lead-out patterns (not shown) of wiring patterns are led out from the respective connecting land portions 7. Moreover, as described above, the elastic pieces 9 of the respective conductive metal pieces 10 are individually in elastic-contact with the respective connecting land portions 7 so that they are mechanically and electrically connected. Thus, these connecting land portions 7 are individually electrically connected to the nine terminal electrodes 6.

As above, in the SD card 1 according to the present embodiment, the terminal electrodes 6 which are fixed near one side edge of the housing 4 (the lower cover 3) are electrically connected to the connecting land portions 7 (parts of wiring patterns) of the circuit board 5 through the conductive elastic pieces 9. Moreover, it is not necessary to form terminal electrodes on the principal surface 5a of the circuit board 5. Thus, it is possible to secure the high inner space S in the housing 4 easily even when the outside dimensions of the housing 4 and the height position of the terminal electrodes 6 are set according to the standards. Therefore, even when an additional function is added to the SD card 1 by mounting the tall electronic component 8a on the circuit board 5 so as to enable radio communication, the appearance and dimensions thereof are equivalent to those of typical SD cards. Thus, the SD card 1 can be fitted into the SD card slot of the external electronic device and used.

Moreover, in the SD card 1, the respective terminal electrodes 6 are fixed to the housing 4, and the respective elastic pieces 9 are in elastic-contact with the connecting land portions 7 at one end of the principal surface 5a of the circuit board 5. Therefore, it is possible to secure a wide mounting region on the principal surface 5a of the circuit board 5 as shown in FIG. 5, and accordingly, to make circuit design easy. In addition, the respective terminal electrodes 6 are fixed to the housing 4 (the lower cover 3) by insert molding, and the terminal electrodes 6 and the elastic pieces 9 are integral products. Thus, it is easy to assemble the SD card 1.

Moreover, in the SD card 1, since the respective elastic pieces 9 are in elastic-contact with the corresponding connecting land portions 7 of the circuit board 5 within the housing 4, the clamping force applied to the housing 4 when attaching and removing the SD card 1 to/from the card slot of the external electronic device acts as an external force that elastically deforms the respective elastic pieces 9. Thus, the clamping force is not likely to generate stress that impairs the conduction between the elastic pieces 9 and the connecting land portions 7. As a result, conduction faults of the terminal electrodes 6 are not likely to occur. In the present embodiment, reliability of conduction is enhanced by connecting the distal ends of the elastic pieces 9 to the connecting land portions 7 using solders or a conductive adhesive agent. However, even when such a connection means is not used, since the elastic pieces 9 are in elastic-contact with the connecting land portions 7, conduction between both 7 and 9 will be maintained easily.

Moreover, a plurality of reinforcing ribs 3d which protrudes from the vicinity of the terminal electrodes 6 and makes contact with the principal surface 5a of the circuit board 5 is formed on the housing 4 (the lower cover 3) of the SD card 1. Thus, the clamping force applied to the housing 4 when attaching and removing the SD card 1 to/from the card slot of the external electronic device can be received by these reinforcing ribs 3d. Therefore, it is possible to suppress positional shifts of the terminal electrodes 6 and the elastic pieces 9 due to the clamping force as much as possible and to extend the lifespan of the SD card 1.

In the embodiment above, reduction in the number of components and improvement in reliability of conduction are realized by a configuration in which the elastic pieces 9 extending from the terminal electrodes 6 to the inside of the housing 4 are in elastic-contact with the connecting land portions 7 of the circuit board 5. The connecting land portions 7 may be electrically connected to the terminal electrodes 6 within the housing 4 using elastic members which are formed of a conductive material and formed separately from the terminal electrodes 6. For example, approximately equivalent effects can be obtained when conductive spring members or rubber members are used as the elastic members (internal connection means) and are interposed between the rear surfaces of the terminal electrodes 6 and the connecting land portions 7 within the housing 4 in compressed state. In this case, the number of components may increase as compared to the embodiment above.

In the embodiment above, although the invention is applied to an SD card, the invention can be also applied to other card-type electronic circuit modules as represented by memory cards other than the SD card.

It should be understood by those skilled in the art that various modifications, combinations, sub-combinations and alterations may occur depending on design requirements and other factors insofar as they are within the scope of the appended claims of the equivalents thereof.

1. A card-type electronic circuit module comprising:
a circuit board on which wiring patterns are formed and electronic components are mounted;
an insulating housing in which the circuit board is accommodated;
terminal electrodes which are fixed near one side end of the housing and exposed to the outside; and
conductive internal connection means for realizing conduction between the terminal electrodes and the wiring patterns within the housing,
wherein the circuit board is extended along one of mutually facing inner walls of the housing, and the internal connection means are in elastic-contact with connecting land portions of the wiring patterns disposed at one end of the principal surface of the circuit board.

2. The card-type electronic circuit module according to claim 1, wherein the terminal electrodes are fixed to the housing by insert molding.

3. The card-type electronic circuit module according to claim 1, wherein the internal connection means are realized by elastic pieces which extend from the terminal electrodes to the inside of the housing, and distal ends of the elastic pieces are in elastic-contact with the connecting land portions.

4. The card-type electronic circuit module according to claims 1, wherein reinforcing ribs which protrude from the vicinity of the terminal electrodes and make contact with the principal surface of the circuit board are formed on the housing.

5. The card-type electronic circuit module according to claim 2, wherein the internal connection means are realized by elastic pieces which extend from the terminal electrodes to the inside of the housing, and distal ends of the elastic pieces are in elastic-contact with the connecting land portions.

6. The card-type electronic circuit module according to claim 2, wherein reinforcing ribs which protrude from the vicinity of the terminal electrodes and make contact with the principal surface of the circuit board are formed on the housing.

7. The card-type electronic circuit module according to claim 3, wherein reinforcing ribs which protrude from the vicinity of the terminal electrodes and make contact with the principal surface of the circuit board are formed on the housing.
